(19) United States
(12) Patent Application Publication
(10) Pub. No.: US 2026/0129890 A1
(43) Pub. Date: May 7, 2026

(54) SEMICONDUCTOR DEVICE

(71) Applicant: DENSO CORPORATION, Kariya-city (JP)

(72) Inventors: Kosuke OTA, Kariya-city (JP); Masakiyo SUMITOMO, Kariya-city (JP); Shigeki TAKAHASHI, Kariya-city (JP)

(21) Appl. No.: 19/436,775

(22) Filed: Dec. 30, 2025

Related U.S. Application Data
(63) Continuation of application No. PCT/JP2024/015415, filed on Apr. 18, 2024.

(30) Foreign Application Priority Data
Jul. 3, 2023 (JP) 2023-109289

(51) Int. Cl. H10D 12/00; H10D 30/66; H10D 62/13; H10D 62/60

(52) U.S. Cl. CPC H10D 12/418; H10D 12/421; H10D 12/441; H10D 30/662; H10D 62/133; H10D 62/137; H10D 62/153; H10D 62/157; H10D 62/60

(57) ABSTRACT

A semiconductor device includes, within an outer peripheral region: an outer peripheral p-type layer; an outer peripheral n-type layer positioned on an outer peripheral side relative to the outer peripheral p-type layer with a space from the outer peripheral p-type layer; a high breakdown voltage p-type layer arranged to include a portion of an upper surface of a semiconductor substrate located between the outer peripheral p-type layer and the outer peripheral n-type layer; a drift n-type layer extending up to the upper surface between the high breakdown voltage p-type layer and the outer peripheral n-type layer; a protective electrode disposed above the high breakdown voltage p-type layer via an interlayer insulating film and electrically connected to an upper electrode; and a semi-insulating film covering the upper surface between the protective electrode and the outer peripheral n-type layer and having a resistivity of 1×10⁸ Ω·cm to 1×10¹⁴ Ω·cm at 25° C.

### CROSS REFERENCE TO RELATED APPLICATIONS

The present application is a continuation application of International Patent Application No. PCT/JP2024/015415 filed on Apr. 18, 2024, which designated the U.S. and claims the benefit of priority from Japanese Patent Application No. 2023-109289 filed on Jul. 3, 2023. The entire disclosures of all of the above applications are incorporated herein by reference.

### TECHNICAL FIELD

The present disclosure relates to a semiconductor device.

### BACKGROUND

Conventionally, semiconductor devices having an element region provided with a semiconductor element and an outer peripheral region disposed around the element region have been known.

### SUMMARY

A semiconductor device according to one aspect of the present disclosure includes: a semiconductor substrate having an upper surface and a lower surface; an upper electrode disposed in contact with the upper surface of the semiconductor substrate; a lower electrode disposed in contact with the lower surface of the semiconductor substrate; a protective electrode electrically connected to the upper electrode; and a semi-insulating film having a resistivity of greater than or equal to 1×10⁸ Ω·cm and less than or equal to 1×10¹⁴ Ω·cm at 25° C. The semiconductor substrate has an element region located below a contact portion between the upper electrode and the upper surface, and an outer peripheral region located between the element region and an outer peripheral end face of the semiconductor substrate. The semiconductor substrate includes: an element p-type layer disposed within the element region and in contact with the upper electrode; an outer peripheral p-type layer disposed within the outer peripheral region, arranged to include the upper surface, and in contact with the element p-type layer; an outer peripheral n-type layer disposed within the outer peripheral region, arranged to include the upper surface, and positioned on an outer peripheral side relative to the outer peripheral p-type layer with a space from the outer peripheral p-type layer; a high breakdown voltage p-type layer disposed within the outer peripheral region, arranged to include a portion of the upper surface located between the outer peripheral p-type layer and the outer peripheral n-type layer; and a drift n-type layer extending from a position below the element p-type layer to a position below the outer peripheral n-type layer, having an n-type impurity concentration lower than an n-type impurity concentration of the outer peripheral n-type layer, and extending up to the upper surface between the high breakdown voltage p-type layer and the outer peripheral n-type layer. The protective electrode may be disposed above the high breakdown voltage p-type layer via an interlayer insulating film. The semi-insulating film may cover the upper surface between the protective electrode and the outer peripheral n-type layer, and may electrically connect the protective electrode and the outer peripheral n-type layer.

### BRIEF DESCRIPTION OF DRAWINGS

Objects, features and advantages of the present disclosure will become apparent from the following detailed description made with reference to the accompanying drawings. In the drawings:

FIG. 1 is a plan view of a semiconductor device according to an embodiment as seen from above;

FIG. 2 is a cross-sectional view of the semiconductor device taken along line II-II in FIG. 1;

FIG. 3 is a diagram showing a potential distribution when a rated voltage is applied at room temperature to the semiconductor device according to the embodiment;

FIG. 4 is a diagram showing a potential distribution when a rated voltage is applied at room temperature to a semiconductor device of a comparative example;

FIG. 5 is a diagram showing a potential distribution when the rated voltage is applied at a high temperature to the semiconductor device according to the embodiment;

FIG. 6 is a diagram showing a potential distribution when the rated voltage is applied at a high temperature to the semiconductor device of the comparative example;

FIG. 7 is a cross-sectional view of a semiconductor device according to a first modification;

FIG. 8 is a cross-sectional view of a semiconductor device according to a second modification; and

FIG. 9 is a cross-sectional view of a semiconductor device according to a third modification.

### DETAILED DESCRIPTION

Next, relevant technology is described to facilitate understanding of the following embodiments. A semiconductor device includes an element region provided with a semiconductor element, and an outer peripheral region disposed around the element region. The outer peripheral region has a high breakdown voltage structure such as a reduced surface field (RESURF) layer or a guard ring. In the semiconductor device, a surface of the semiconductor substrate within the outer peripheral region is covered with a semi-insulating film. Furthermore, in the semiconductor device, an n⁺-type semiconductor region is disposed on an outer peripheral side relative to the high breakdown voltage structure. The semi-insulating film electrically connects an upper electrode in the element region with the n⁺-type semiconductor layer. Since a minute current flows through the semi-insulating film, a potential difference is generated within the semi-insulating film. The potential difference generated in the semi-insulating film suppresses the unevenness of the potential distribution within a semiconductor layer in the outer peripheral region. Accordingly, the semiconductor device has a high breakdown voltage.

A resistivity of the semi-insulating film decreases at high temperatures. When the resistivity of the semi-insulating film decreases, the potential difference generated within the semi-insulating film becomes smaller, resulting in electric field concentration occurring at a position within the outer peripheral region closer to the element region. Thus, the high breakdown voltage structure utilizing the semi-insulating film exhibits a decrease in breakdown voltage when the temperature of the semiconductor device rises.

A semiconductor device according to one aspect of the present disclosure includes: a semiconductor substrate having an upper surface and a lower surface; an upper electrode disposed in contact with the upper surface of the semiconductor substrate; a lower electrode disposed in contact with the lower surface of the semiconductor substrate; a protective electrode electrically connected to the upper electrode; and a semi-insulating film having a resistivity of greater than or equal to 1×10⁸ Ω·cm and less than or equal to 1×10¹⁴ Ω·cm at 25° C. The semiconductor substrate has an element region located below a contact portion between the upper electrode and the upper surface, and an outer peripheral region located between the element region and an outer peripheral end face of the semiconductor substrate. The semiconductor substrate includes: an element p-type layer disposed within the element region and in contact with the upper electrode; an outer peripheral p-type layer disposed within the outer peripheral region, arranged to include the upper surface, and in contact with the element p-type layer; an outer peripheral n-type layer disposed within the outer peripheral region, arranged to include the upper surface, and positioned on an outer peripheral side relative to the outer peripheral p-type layer with a space from the outer peripheral p-type layer; a high breakdown voltage p-type layer disposed within the outer peripheral region, arranged to include a portion of the upper surface located between the outer peripheral p-type layer and the outer peripheral n-type layer; and a drift n-type layer extending from a position below the element p-type layer to a position below the outer peripheral n-type layer, having an n-type impurity concentration lower than an n-type impurity concentration of the outer peripheral n-type layer, and extending up to the upper surface between the high breakdown voltage p-type layer and the outer peripheral n-type layer. The protective electrode is disposed above the high breakdown voltage p-type layer via an interlayer insulating film. The semi-insulating film covers the upper surface between the protective electrode and the outer peripheral n-type layer, and electrically connects the protective electrode and the outer peripheral n-type layer.

In the present disclosure, the term “outer peripheral side” refers to a side closer to an outer peripheral edge of the semiconductor substrate. On the other hand, the term “inner peripheral side” refers to a side closer to a center of the semiconductor substrate.

The high breakdown voltage p-type layer may be a RESURF layer, a guard ring, or may include both of these.

In addition, the semi-insulating film covering the upper surface of the semiconductor substrate may be in contact with, or not in contact with, the upper surface of the semiconductor substrate. For example, another layer (such as an interlayer insulating film) may be disposed between the semi-insulating film and the upper surface of the semiconductor substrate.

In this semiconductor device, the protective electrode is present above the high breakdown voltage p-type layer. The protective electrode is electrically connected to the upper electrode and has a potential substantially equal to that of the upper electrode. Therefore, even if the resistivity of the semi-insulating film decreases, electric field concentration within the semiconductor layer on the inner peripheral side relative to the protective electrode is suppressed. Therefore, in this semiconductor device, the breakdown voltage is less likely to decrease when the temperature rises.

In one aspect of the present disclosure, the high breakdown voltage p-type layer may be in contact with the outer peripheral p-type layer, may be shallower than the outer peripheral p-type layer, and may have a p-type impurity concentration lower than that of the outer peripheral p-type layer. An outer peripheral end of the protective electrode may be located on the inner peripheral side relative to an outer peripheral end of the high breakdown voltage p-type layer.

According to this configuration, it is possible to disperse a location of electric field concentration within the outer peripheral region, thereby achieving a high breakdown voltage.

In one aspect of the present disclosure, the outer peripheral end of the protective electrode may be located on the inner peripheral side relative to an inner peripheral end of a depletion layer formed within the high breakdown voltage p-type layer when a rated voltage is applied between the upper electrode and the lower electrode at 25° C.

According to this configuration, since the protective electrode does not affect the potential distribution within the depletion layer at room temperature, a high breakdown voltage can be achieved at room temperature.

In one aspect of the present disclosure, the semi-insulating film has a thickness that decreases from the inner peripheral side toward the outer peripheral side.

According to this configuration, concentration of the electric field in the outer peripheral region can be suppressed more effectively.

In one aspect of the present disclosure, the semi-insulating film may have a resistivity that increases from the inner peripheral side toward the outer peripheral side.

According to this configuration, concentration of the electric field in the outer peripheral region can be suppressed more effectively.

### EMBODIMENTS

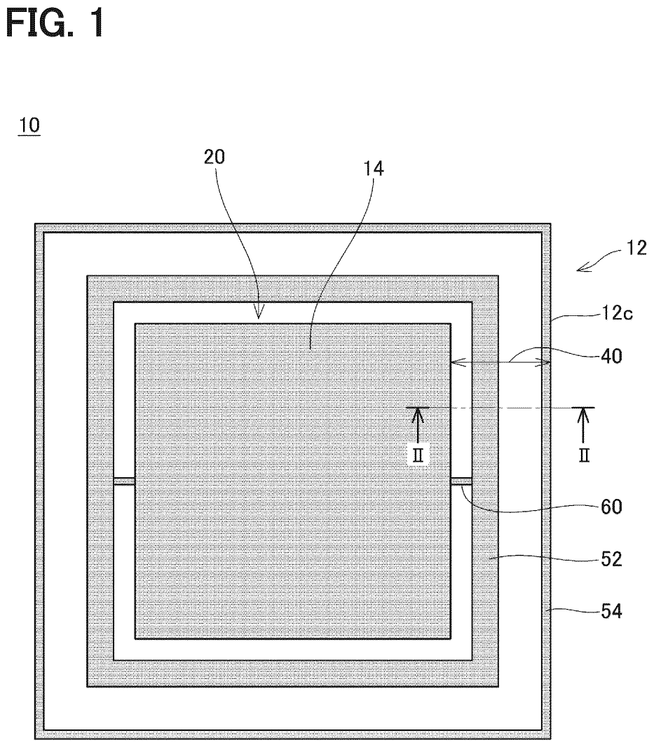

A semiconductor device 10 according to an embodiment of the present embodiment includes a semiconductor substrate 12 as shown in FIG. 1. On an upper portion of the semiconductor substrate 12, an upper electrode 14 is disposed. The upper electrode 14 is formed from a material such as AlSi. The upper electrode 14 is disposed at a central portion of the upper surface of the semiconductor substrate 12. The upper electrode 14 is in contact with the upper surface of the semiconductor substrate 12. Hereinafter, a semiconductor region below a contact area between the upper electrode 14 and the upper surface of the semiconductor substrate 12 is referred to as an element region 20. Furthermore, hereinafter, a semiconductor region surrounding the element region 20 within the semiconductor substrate 12 is referred to as an outer peripheral region 40. That is, the outer peripheral region 40 is a semiconductor region located between the element region 20 and an outer peripheral end face 12c of the semiconductor substrate 12. In the outer peripheral region 40, the upper surface of the semiconductor substrate 12 is not in contact with the upper electrode 14.

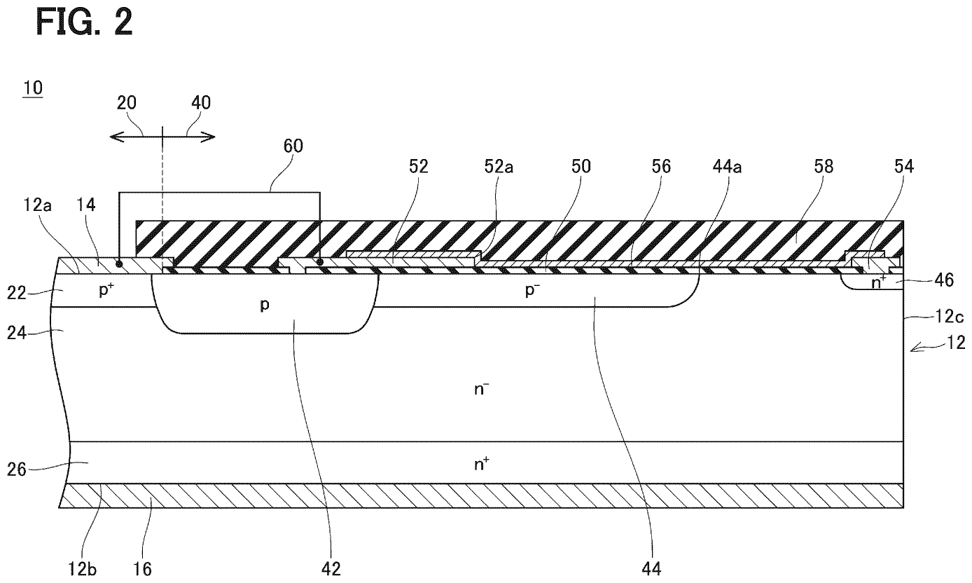

As shown in FIG. 2, the upper electrode 14 is in contact with the upper surface 12a of the semiconductor substrate 12 within the element region 20. On a lower surface 12b of the semiconductor substrate 12, a lower electrode 16 is disposed. The lower electrode 16 is in contact with the lower surface 12b of the semiconductor substrate 12 over a range spanning both the element region 20 and the outer peripheral region 40.

Within the element region 20, a lower n-type layer 26, a drift n-type layer 24, and an element p-type layer 22 are disposed.

The lower n-type layer 26 has a high n-type impurity concentration. The lower n-type layer 26 is disposed across both the element region 20 and the outer peripheral region 40. The lower n-type layer 26 is in ohmic contact with the lower electrode 16 over a range spanning both the element region 20 and the outer peripheral region 40.

The drift n-type layer 24 has a lower n-type impurity concentration than the lower n-type layer 26. The drift n-type layer 24 is disposed across both the element region 20 and the outer peripheral region 40. The drift n-type layer 24 is in contact with the lower n-type layer 26 from above over a range spanning both the element region 20 and the outer peripheral region 40.

The element p-type layer 22 has a high p-type impurity concentration. The element p-type layer 22 is in contact with the drift n-type layer 24 from above within the element region 20. The element p-type layer 22 is disposed in a region including the upper surface 12a of the semiconductor substrate 12, and is in ohmic contact with the upper electrode 14.

Within the element region 20, a diode is formed by the lower n-type layer 26, the drift n-type layer 24, and the element p-type layer 22. The element p-type layer 22 functions as an anode layer, and the lower n-type layer 26 functions as a cathode layer. It should be noted that, in other embodiments, other semiconductor elements may also be formed within the element region 20. For example, a field effect transistor (FET) or an insulated gate bipolar transistor (IGBT) may be provided within the element region 20. When an FET is provided within the element region 20, the element p-type layer 22 may function as a body layer (that is, a layer in which a channel is formed), and the lower n-type layer 26 may function as a drain layer. When an IGBT is provided within the element region 20, the element p-type layer 22 may function as a body layer (that is, a layer in which a channel is formed), and a p-type collector region may be provided instead of the lower n-type layer 26. The semiconductor element provided within the element region 20 may be any semiconductor element capable of allowing current to flow between the upper electrode 14 and the lower electrode 16.

Within the outer peripheral region 40, an outer peripheral p-type layer 42, a high breakdown voltage p-type layer 44, and an outer peripheral n-type layer 46 are disposed.

The outer peripheral p-type layer 42 is disposed in a region including the upper surface 12a of the semiconductor substrate 12. The outer peripheral p-type layer 42 extends downward from the upper surface 12a to a position below a lower end of the element p-type layer 22. The outer peripheral p-type layer 42 has a lower p-type impurity concentration than the element p-type layer 22. The outer peripheral p-type layer 42 is in contact with the element p-type layer 22 from an outer peripheral side.

The outer peripheral n-type layer 46 is disposed in a region including the upper surface 12a of the semiconductor substrate 12. The outer peripheral n-type layer 46 is disposed on the outer peripheral side relative to the outer peripheral p-type layer 42, with a space between the outer peripheral n-type layer 46 and the outer peripheral p-type layer 42. More specifically, the outer peripheral n-type layer 46 is disposed in a region including an outer-peripheral end portion of the upper surface 12a and an upper end portion of the outer peripheral end face 12c. The outer peripheral n-type layer 46 has a higher n-type impurity concentration than the drift n-type layer 24.

The high breakdown voltage p-type layer 44 is disposed in a region including a portion of the upper surface 12a located between the outer peripheral p-type layer 42 and the outer peripheral n-type layer 46. In the present embodiment, the high breakdown voltage p-type layer 44 is a RESURF layer. The high breakdown voltage p-type layer 44 is in contact with the outer peripheral p-type layer 42 on the outer peripheral side. A space is provided between the high breakdown voltage p-type layer 44 and the outer peripheral n-type layer 46. The high breakdown voltage p-type layer 44 extends from the upper surface 12a to a position above a lower end of the outer peripheral p-type layer 42. That is, the high breakdown voltage p-type layer 44 is disposed in a shallower region than the outer peripheral p-type layer 42. The high breakdown voltage p-type layer 44 has a lower p-type impurity concentration than the outer peripheral p-type layer 42.

As described above, the drift n-type layer 24 is disposed across both the element region 20 and the outer peripheral region 40. The drift n-type layer 24 is in contact with the outer peripheral p-type layer 42, the high breakdown voltage p-type layer 44, and the outer peripheral n-type layer 46 from below. In addition, the drift n-type layer 24 extends up to the upper surface 12a at a position between the high breakdown voltage p-type layer 44 and the outer peripheral n-type layer 46. The high breakdown voltage p-type layer 44 is separated from the outer peripheral n-type layer 46 by the drift n-type layer 24.

On the upper surface 12a of the semiconductor substrate 12 within the outer peripheral region 40, an interlayer insulating film 50, a protective electrode 52, an equi-potential ring (EQR) electrode 54, a semi-insulating film 56, and an insulating protective film 58 are disposed.

The interlayer insulating film 50 covers the upper surface 12a within an area where the outer peripheral p-type layer 42, the high breakdown voltage p-type layer 44, the drift n-type layer 24, and the outer peripheral n-type layer 46 are exposed. The interlayer insulating film 50 is in contact with the upper surface 12a.

The protective electrode 52 is disposed on the interlayer insulating film 50. The protective electrode 52 is formed of a material such as AlSi. As shown in FIG. 1, the protective electrode 52 extends in an annular shape so as to surround a periphery of the upper electrode 14. As shown in FIG. 2, the protective electrode 52 extends from a position above the outer peripheral p-type layer 42 to a position above the high breakdown voltage p-type layer 44. An outer peripheral end 52a of the protective electrode 52 is disposed at a position above the high breakdown voltage p-type layer 44. That is, the outer peripheral end 52a of the protective electrode 52 is disposed on an inner peripheral side (that is, at a position closer to the element region 20) relative to an outer peripheral end 44a of the high breakdown voltage p-type layer 44. The protective electrode 52 is connected to the outer peripheral p-type layer 42 via a contact hole formed in the interlayer insulating film 50. However, in other embodiments, the protective electrode 52 may be separated from the outer peripheral p-type layer 42 by the interlayer insulating film 50.

A gap is provided between the protective electrode 52 and the upper electrode 14. As shown in FIG. 1, a wiring layer 60 is disposed on a part of the periphery of the upper electrode 14. The protective electrode 52 and the upper electrode 14 are electrically connected by the wiring layer 60. Therefore, the protective electrode 52 has the same potential as the upper electrode 14. In other embodiments, a wiring layer (for example, a gate wiring layer) insulated from the protective electrode 52 and the upper electrode 14 may be provided on the interlayer insulating film 50 at a position between the protective electrode 52 and the upper electrode 14. In cases where no wiring layer is disposed at the position between the protective electrode 52 and the upper electrode 14, the protective electrode 52 may be directly connected to the upper electrode 14.

As shown in FIG. 2, the EQR electrode 54 is disposed on the interlayer insulating film 50. The EQR electrode 54 is composed of a material such as AlSi. The EQR electrode 54 is disposed on an upper portion of the outer peripheral n-type layer 46. As shown in FIG. 1, the EQR electrode 54 extends in an annular shape along the outer peripheral edge of the semiconductor substrate 12. As shown in FIG. 2, the EQR electrode 54 is connected to the outer peripheral n-type layer 46 via a contact hole provided in the interlayer insulating film 50.

The semi-insulating film 56 is composed of semi-insulating silicon nitride (SInSiN). The semi-insulating film 56 has a resistivity of greater than or equal to 1×10⁸ Ω·cm and less than or equal to 1×10¹⁴ Ω·cm at 25° C. The semi-insulating film 56 has a characteristic that its resistivity decreases with an increase in temperature. The semi-insulating film 56 extends from an upper surface of the protective electrode 52 to an upper surface of the EQR electrode 54. The semi-insulating film 56 covers the upper surface 12a between the protective electrode 52 and the EQR electrode 54. In the present embodiment, the semi-insulating film 56 is disposed on the interlayer insulating film 50 between the protective electrode 52 and the EQR electrode 54. However, in other embodiments, the semi-insulating film 56 may be in contact with the upper surface 12a of the semiconductor substrate 12. The protective electrode 52 is electrically connected to the outer peripheral n-type layer 46 via the semi-insulating film 56 and the EQR electrode 54.

The insulating protective film 58 is disposed at an uppermost portion of the outer peripheral region 40. The insulating protective film 58 covers the interlayer insulating film 50, the protective electrode 52, the EQR electrode 54, and the semi-insulating film 56.

When a potential higher than that of the upper electrode 14 is applied to the lower electrode 16, a depletion layer extends from the p-type layer, which is composed of the element p-type layer 22, the outer peripheral p-type layer 42, and the high breakdown voltage p-type layer 44, into the drift n-type layer 24. As a result, substantially the entire region of the drift n-type layer 24 is depleted. Furthermore, since the p-type impurity concentration of the high breakdown voltage p-type layer 44 is low, the depletion layer extends from the drift n-type layer 24 into the high breakdown voltage p-type layer 44. The voltage between the lower electrode 16 and the upper electrode 14 is maintained by the depletion layer spreading within the high breakdown voltage p-type layer 44 and the drift n-type layer 24.

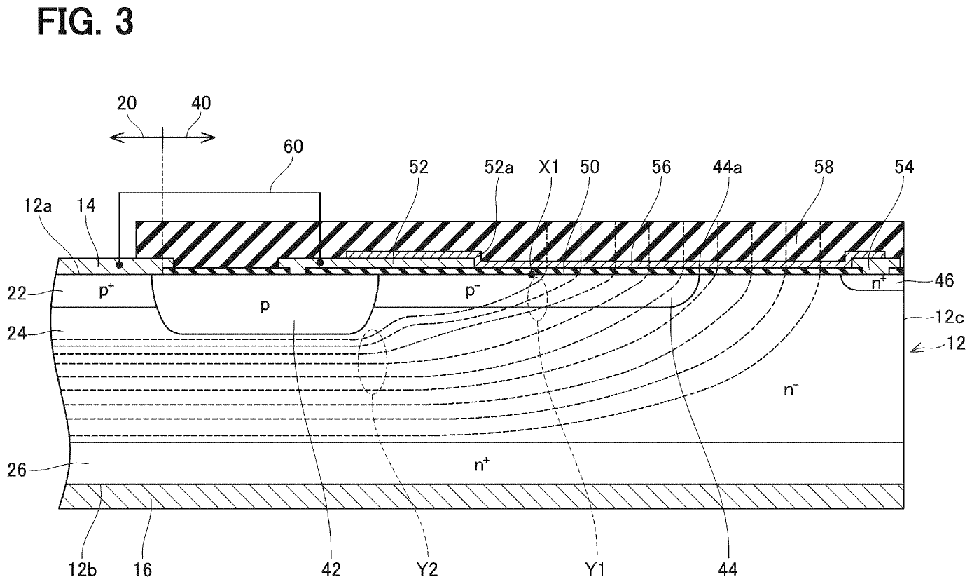

FIG. 3 schematically shows a potential distribution in the semiconductor device 10 in a state where a rated voltage is applied such that the lower electrode 16 is at a higher potential than the upper electrode 14. FIG. 3 shows the potential distribution at room temperature. Since the potential of the lower electrode 16 is higher than that of the upper electrode 14, the potential within the element region 20 is distributed such that it decreases from the lower side toward the upper side. Additionally, the potential at the outer peripheral end face 12c of the semiconductor substrate 12 is approximately equal to the potential of the lower electrode 16. That is, the potential of the outer peripheral n-type layer 46 and the EQR electrode 54 is approximately equal to the potential of the lower electrode 16. Therefore, within the outer peripheral region 40, the potential is distributed such that it decreases from the outer peripheral side toward the inner peripheral side.

When a rated voltage is applied to the lower electrode 16, a depletion layer extends from the outer peripheral end 44a of the high breakdown voltage p-type layer 44 toward the inner peripheral side (that is, into the interior of the high breakdown voltage p-type layer 44). In each of FIGS. 3 to 6, a position X1 indicates the location of the inner peripheral end of the depletion layer within the high breakdown voltage p-type layer 44. That is, on the outer peripheral side of the position X1, the high breakdown voltage p-type layer 44 is depleted. Therefore, a potential difference is generated within the high breakdown voltage p-type layer 44 on the outer peripheral side of the position X1.

As described above, the outer peripheral n-type layer 46 has a potential approximately equal to that of the lower electrode 16. In addition, the protective electrode 52 has a potential approximately equal to that of the upper electrode 14. Since the outer peripheral end 52a of the protective electrode 52 is positioned on the inner peripheral side of the position X1, the potential distribution on the outer peripheral side of the position X1 (that is, the potential distribution within the depletion layer in the high breakdown voltage p-type layer 44) is not disturbed by the protective electrode 52. In this manner, electric field concentration is suppressed in a region on the outer peripheral side of the position X1. In a region Y1 directly below the position X1 (that is, directly below an edge of the depletion layer), the electric field is concentrated. Additionally, since the outer peripheral p-type layer 42 protrudes further downward than the high breakdown voltage p-type layer 44, the electric field is also concentrated in a region Y2 at a lower portion of a boundary between the outer peripheral p-type layer 42 and the high breakdown voltage p-type layer 44. In this way, since the location of electric field concentration is dispersed into the regions Y1 and Y2, the occurrence of excessively high electric fields is suppressed. Therefore, at room temperature, the semiconductor device 10 of the present embodiment has a high breakdown voltage.

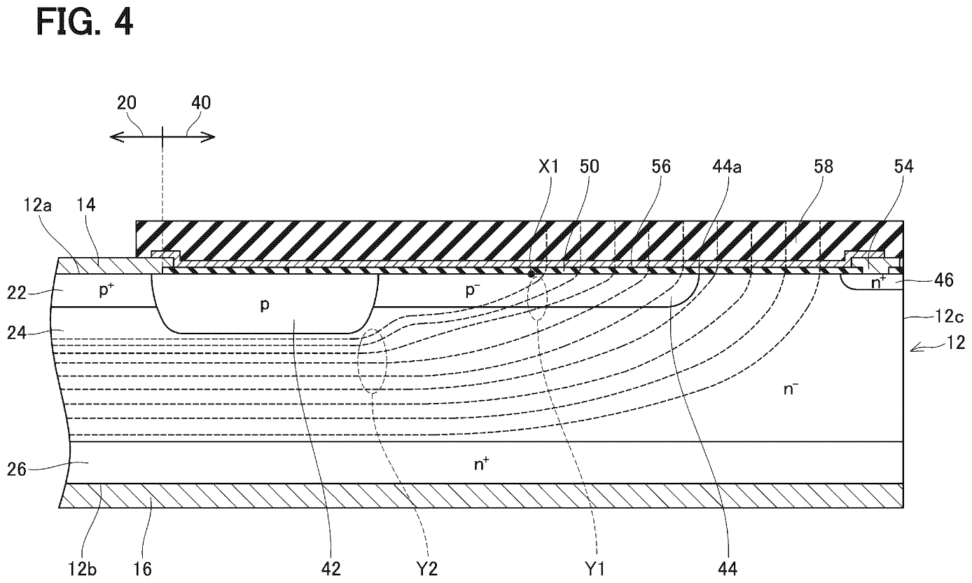

FIG. 4 shows a potential distribution when a rated voltage is applied at room temperature to a semiconductor device according to a comparative example. It should be noted that in the semiconductor device of the comparative example, there is no protective electrode 52 above the high breakdown voltage p-type layer 44, and the semi-insulating film 56 connects the EQR electrode 54 to the upper electrode 14. In other respects, the structure of the semiconductor device of the comparative example is similar to that of the semiconductor device according to the present embodiment. As shown in FIG. 4, even in the semiconductor device of the comparative example, as in the semiconductor device 10 of the present embodiment, the location of the electric field concentration is dispersed into the regions Y1 and Y2. Therefore, at room temperature, the semiconductor device of the comparative example has a breakdown voltage similar to that of the semiconductor device 10 of the present embodiment.

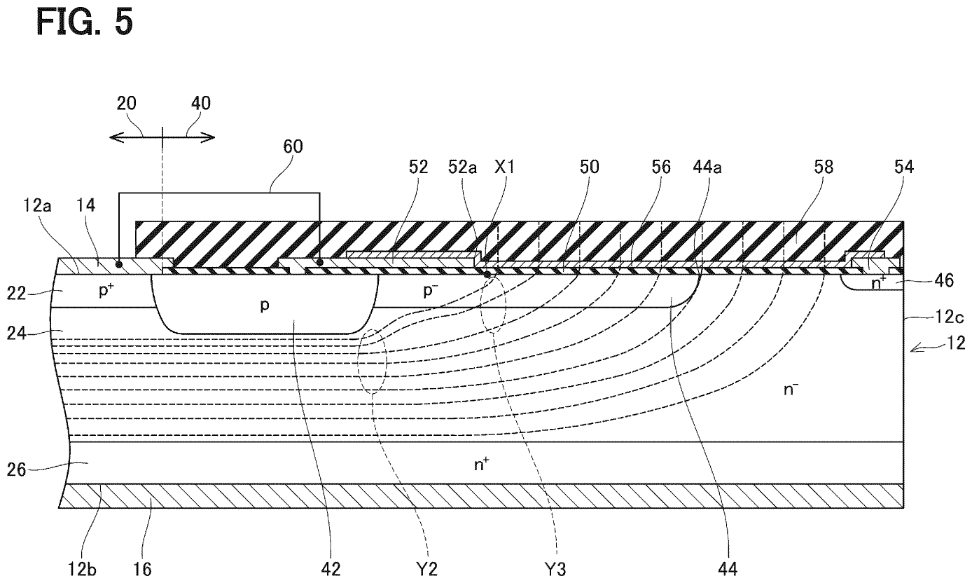

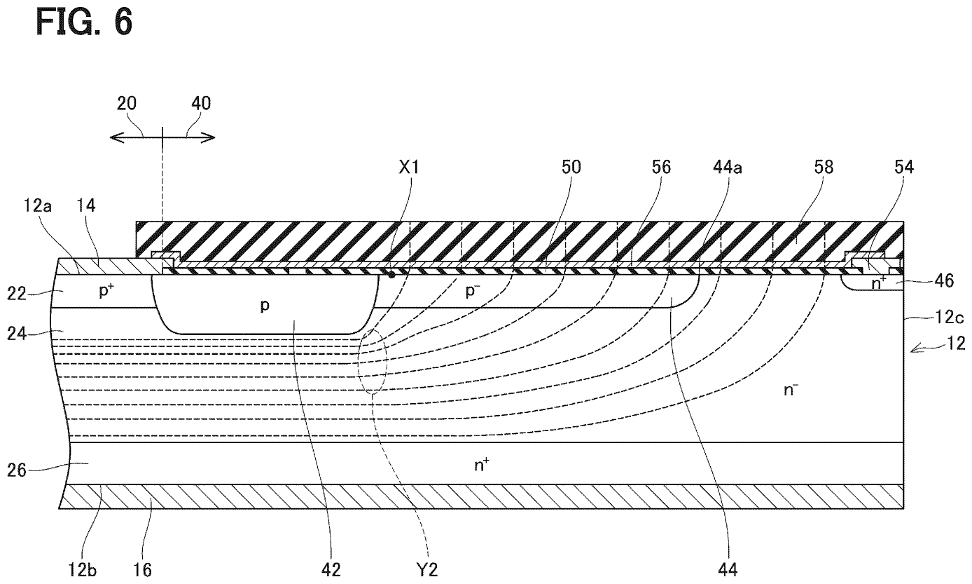

FIG. 5 shows a potential distribution when the rated voltage is applied at a high temperature to the semiconductor device 10 of the present embodiment. In addition, FIG. 6 shows a potential distribution when the rated voltage is applied at high temperature to the semiconductor device of the comparative example. As described above, when the temperature of the semi-insulating film 56 rises, the resistivity of the semi-insulating film 56 decreases. When the resistivity of the semi-insulating film 56 decreases, the potential difference generated within the semi-insulating film 56 becomes smaller. Therefore, the space between equipotential lines within the semi-insulating film 56 becomes wider.

As shown in FIG. 6, in the semiconductor device of the comparative example, the distribution range of the depletion layer expands with an increase in the space between equipotential lines within the semi-insulating film 56. Therefore, the position X1 of the end of the depletion layer moves toward the vicinity of the outer peripheral p-type layer 42. When the end of the depletion layer is located in the vicinity of the outer peripheral p-type layer 42 in this manner, the location of electric field concentration is not dispersed. That is, the electric field is concentrated at a single location, specifically in a region Y2 below the boundary between the outer peripheral p-type layer 42 and the high breakdown voltage p-type layer 44, resulting in an excessively high electric field in the region Y2. In this way, in the semiconductor device of the comparative example, the breakdown voltage decreases when the temperature rises.

In contrast, as shown in FIG. 5, in the semiconductor device 10 of the present embodiment, since the protective electrode 52, which is fixed at the same potential as the upper electrode 14, is present above the high breakdown voltage p-type layer 44, the depletion layer cannot extend to the inner peripheral side beyond the protective electrode 52. Therefore, even if the resistivity of the semi-insulating film 56 decreases, the position X1 of the end of the depletion layer will be located on the outer peripheral side of the protective electrode 52. For this reason, it is possible to prevent the position X1 from excessively approaching the outer peripheral p-type layer 42. Therefore, in FIG. 5, the electric field concentration is distributed into the region Y2 and the range Y3 below the outer peripheral end 52a of the protective electrode 52. That is, it is possible to prevent the electric field from concentrating at a single location within the range Y2. As a result, the generation of excessively high electric fields is suppressed. As described above, the semiconductor device 10 of the present embodiment has a high breakdown voltage even when the temperature rises.

As described above, according to the structure of the semiconductor device 10 of the present embodiment, a high breakdown voltage can be achieved both at room temperature and at high temperatures. In experiments, with this structure, the amount of breakdown voltage reduction at high temperatures of 40° C. or higher decreased by approximately 100 V.

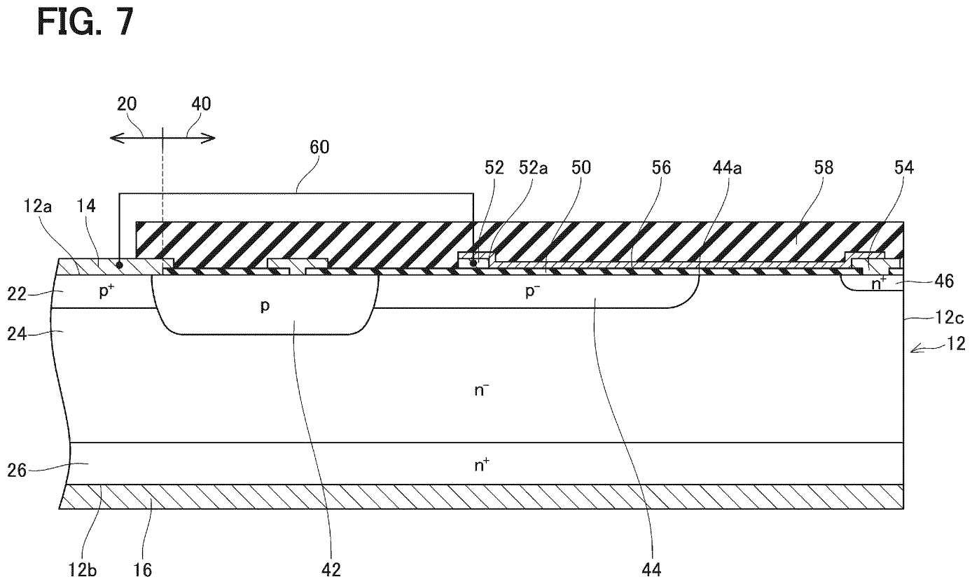

In the present embodiment, the protective electrode 52 is present spanning from the upper portion of the outer peripheral p-type layer 42 to the upper portion of the high breakdown voltage p-type layer 44. However, as a first modification shown in FIG. 7, the protective electrode 52 may be present on the upper portion of the high breakdown voltage p-type layer 44, and does not necessarily need to be present on the upper portion of the outer peripheral p-type layer 42. Even with this configuration, as in the present embodiment, a high breakdown voltage can be achieved both at room temperature and at high temperatures. In this case, the protective electrode 52 may be composed of a material with high processability, such as polysilicon.

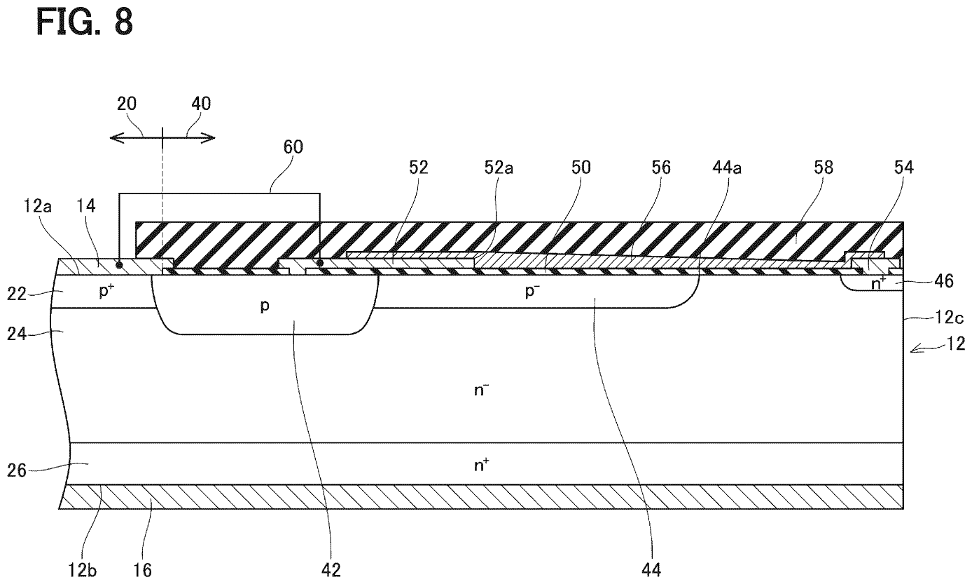

The resistance of the semi-insulating film 56 when a minute current flows (more specifically, the resistance when a minute current flows from the outer peripheral side to the inner peripheral side) may increase from the inner peripheral side toward the outer peripheral side. For example, as a second modification shown in FIG. 8, the thickness of the semi-insulating film 56 may decrease from the inner peripheral side toward the outer peripheral side. Additionally, the resistivity of the semi-insulating film 56 at 25° C. may be distributed so as to increase from the inner peripheral side toward the outer peripheral side. In this configuration, equipotential lines within the semi-insulating film 56 tend to become denser on the outer peripheral side than on the inner peripheral side. Therefore, it is possible to mitigate electric field concentration in the vicinity of the outer peripheral end 52a of the protective electrode 52 at high temperatures.

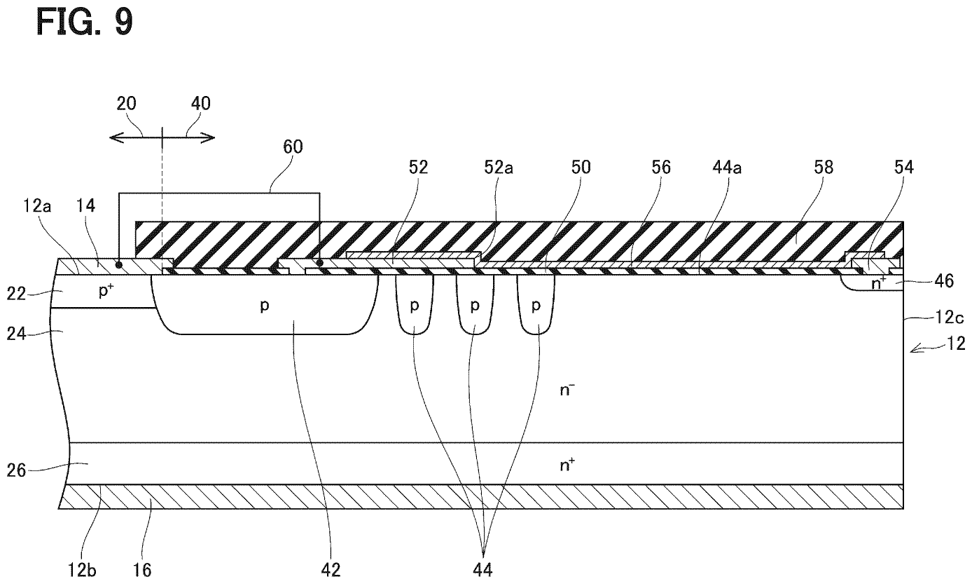

In the above-described embodiment, the high breakdown voltage p-type layer 44 is a RESURF layer. However, as a third modification shown in FIG. 9, the high breakdown voltage p-type layer 44 may also be a guard ring. Even with this configuration, if the resistivity of the semi-insulating film 56 decreases due to a temperature rise, the protective electrode 52 can suppress the depletion layer from approaching the outer peripheral p-type layer 42.

Although the embodiments have been described in detail above, these are merely examples and do not limit the scope of the present disclosure. The technology described in the claims includes various modifications and variations of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve a plurality of objectives at the same time, and achieving one of the objectives itself has technical usefulness.

What is claimed is:

1. A semiconductor device comprising:
a semiconductor substrate having an upper surface and a lower surface;
an upper electrode disposed in contact with the upper surface of the semiconductor substrate;
a lower electrode disposed in contact with the lower surface of the semiconductor substrate;
a protective electrode electrically connected to the upper electrode; and
a semi-insulating film having a resistivity of greater than or equal to 1×10⁸ Ω·cm and less than or equal to 1×10¹⁴ Ω·cm at 25° C., wherein
the semiconductor substrate has:
an element region located below a contact portion between the upper electrode and the upper surface; and
an outer peripheral region located between the element region and an outer peripheral end face of the semiconductor substrate,
the semiconductor substrate includes:
an element p-type layer disposed within the element region and in contact with the upper electrode;
an outer peripheral p-type layer disposed within the outer peripheral region, arranged to include the upper surface, and in contact with the element p-type layer;
an outer peripheral n-type layer disposed within the outer peripheral region, arranged to include the upper surface, and positioned on an outer peripheral side relative to the outer peripheral p-type layer with a space from the outer peripheral p-type layer;
a high breakdown voltage p-type layer disposed within the outer peripheral region, arranged to include a portion of the upper surface located between the outer peripheral p-type layer and the outer peripheral n-type layer; and
a drift n-type layer extending from a position below the element p-type layer to a position below the outer peripheral n-type layer, having an n-type impurity concentration lower than an n-type impurity concentration of the outer peripheral n-type layer, and extending up to the upper surface between the high breakdown voltage p-type layer and the outer peripheral n-type layer,
the protective electrode is disposed above the high breakdown voltage p-type layer via an interlayer insulating film, and
the semi-insulating film covers the upper surface between the protective electrode and the outer peripheral n-type layer, and electrically connects the protective electrode and the outer peripheral n-type layer.

2. The semiconductor device according to claim 1, wherein
the high breakdown voltage p-type layer is in contact with the outer peripheral p-type layer, is shallower than the outer peripheral p-type layer, and has a p-type impurity concentration lower than a p-type impurity concentration of the outer peripheral p-type layer, and
an outer peripheral end of the protective electrode is positioned on an inner peripheral side relative to an outer peripheral end of the high breakdown voltage p-type layer.

3. The semiconductor device according to claim 2, wherein
the outer peripheral end of the protective electrode is positioned on the inner peripheral side relative to an inner peripheral end of a depletion layer that is formed within the high breakdown voltage p-type layer when a rated voltage is applied between the upper electrode and the lower electrode at 25° C.

4. The semiconductor device according to claim 1, wherein
a thickness of the semi-insulating film decreases from an inner peripheral side toward the outer peripheral side.

5. The semiconductor device according to claim 1, wherein
the resistivity of the semi-insulating film increases from an inner peripheral side toward the outer peripheral side.
